(19) United States
(12) Patent Application Publication
(10) Pub. No.: US 2026/0092809 A1
(43) Pub. Date: Apr. 2, 2026

(54) PHOTODETECTOR, ARRAY AND TERMINAL EQUIPMENT

(71) Applicant: SILITH TECHNOLOGY (SUZHOU) CO., LTD., Shanghai (CN)

(72) Inventors: Xingyu ZHANG, Shanghai (CN); Ke ZHANG, Shanghai (CN)

(73) Assignee: SILITH TECHNOLOGY (SUZHOU) CO., LTD., Shanghai (CN)

(21) Appl. No.: 18/994,035

(22) PCT Filed: Oct. 24, 2022
(86) PCT No.: PCT/CN2022/126914

§ 371 Date: Jan. 13, 2025

(30) Foreign Application Priority Data
Jul. 25, 2022 (CN) 202210879924.8

(51) Int. Cl. G01J 1/44; G01J 1/04

(52) U.S. Cl. CPC G01J 1/44; G01J 1/0407

(57) ABSTRACT

The present invention provides a photodetector, array, and equipment. The photodetector comprises a substrate and an optical structure formed on the substrate, wherein the optical structure comprises an optical waveguide and a light absorption layer; the optical waveguide is suspended above an upper side of the light absorption layer and includes a first section and a second section, wherein the first section features a grating structure, and the second section features a tapered structure, the grating structure is designed to diffract incident light and alter the propagation direction of a portion of light; and the light absorption layer is arranged on the substrate and configured to absorb light passing through the grating structure or a portion of light diffracted through the grating structure. The photodetector provided by the present invention exhibits a higher light absorption efficiency.

### CROSS-REFERENCE TO RELATED APPLICATION

The present application claims priority to Chinese Patent Application No. 2022108799248, entitled “Photodetector, Array and Terminal Equipment”, filed on Jul. 25, 2022, the invention of which is incorporated by reference herein.

### TECHNICAL FIELD

The present invention relates to the field of integrated optical devices, and more particularly to a type of photodetector, array and terminal equipment.

### BACKGROUND

Photodetectors have been widely used in various applications, such as optical communication and optical sensing. Photodetectors are designed to absorb light and convert it into a photocurrent. In many photoelectric products like photonics integrated circuits, photodetectors are frequently employed for on-chip power monitoring, high-speed photoelectric demodulation, and more. Responsivity serves as a measure of photoelectric conversion efficiency and stands as a crucial performance parameter for photodetectors. In some applications of integrated photonics, light needs to be coupled from different positions into the absorption region of the photodetector. In some scenarios, such as when light is incident vertically onto the surface of a photodetector, the light may not be effectively coupled to the absorption region of the photodetector, as a portion of the light can penetrate downwards through the absorption region to a substrate and be lost. This leads to the low responsivity of the photodetector, thereby posing a challenge to maintaining high responsivity under such conditions.

Therefore, there is an urgent need to provide a novel photodetector, which can improve light absorption efficiency.

### SUMMARY

An objective of the present invention is to provide a photodetector, which is configured to improve the photoelectric conversion efficiency.

In a first aspect, the present invention provides a photodetector, array and terminal equipment. The photodetector comprises a substrate and an optical structure formed on the substrate, wherein the optical structure comprises an optical waveguide and a light absorption layer; the optical waveguide is suspended above an upper side of the light absorption layer and includes a first section and a second section, wherein the first section has a grating structure, and the second section has a tapered structure, the grating structure is configured to diffract incident light and alter the propagation direction of a portion of light; and the light absorption layer is arranged on the substrate and configured to absorb light passing through the grating structure or a portion of light diffracted through the grating structure.

The photodetector provided by the present invention has the following beneficial effects: the waveguide is configured as a tapered structure, allowing the size of the light beam to gradually expand and be smoothly coupled into an absorption region. As a result, the incident light can be gradually absorbed by the light absorption layer during propagation along the waveguide, leading to a higher photoelectric conversion efficiency of the photodetector. Additionally, the grating structure not only increases the responsivity of the photodetector but also improves its ability to withstand large amounts of incident light, thereby avoiding saturation or damage. The grating structure can be designed as required so that light from any angle of incidence can propagate in any desired direction, so as to improve the interaction between the light and an absorbing material In a possible embodiment, the grating structure is a fully etched grating structure or a shallow etched grating structure, or the grating structure is a multilayer structure.

In another possible embodiment, a grating of the grating structure is bent in a curved shape that focuses toward the second section.

In another possible embodiment, a grating of the grating structure has rectangular side corrugations.

In another possible embodiment, a grating of the grating structure has circular side pillars.

In other possible embodiments, a grating of the grating structure has photonic crystal holes.

In another possible embodiment, the grating structure is arranged on an interface between a lower surface of the light absorption layer and the substrate; and the grating structure is configured to reflect light projected through the absorption layer back toward the light absorption layer.

In another possible embodiment, a light reflection layer is arranged on the lower surface of the substrate away from the light absorption layer, such that light penetrating through the substrate can be reflected to the absorption region at any desired angle, thereby further increasing the responsivity.

In another possible embodiment, the light reflection layer comprises any one of a Bragg reflector, a metal reflector, and a reflective film.

In another possible embodiment, a surface of the first section has a grating structure.

In another possible embodiment, the grating structure is arranged on an upper surface of the light absorption layer adjacent to the optical waveguide.

In another possible embodiment, the photodetector further comprises a circuit layer electrically connected to the light absorption layer, wherein the circuit layer is configured to convert optical signals absorbed by the light absorption layer into electrical signals.

In a second aspect, the present invention further provides a photodetector array, comprising a plurality of photodetectors distributed in an array format, wherein each of the photodetectors is the photodetector according to any one embodiment of the first aspect.

In a third aspect, the present invention further provides a photodetector terminal equipment, comprising a terminal equipment body; and the photodetector array connected to the terminal equipment body according to the second aspect, wherein the terminal equipment body performs photodetection by the photodetector array.

The beneficial effects of the second aspect and the third aspect mentioned above can refer to those of the first aspect and will not be repeated herein.

### BRIEF DESCRIPTION OF THE DRAWINGS

FIG. 1 shows a cross-sectional view and a top view of a photodetector provided by the present invention;

FIG. 2 is a schematic structure diagram of another photodetector with a different optical waveguide structure provided by the present invention;

FIG. 3 is a schematic structure diagram of another photodetector with a different optical waveguide structure provided by the present invention;

FIG. 4 shows schematic structure diagrams of several different grating structures provided by the present invention;

FIG. 5 is a schematic structure diagram of a photodetector with a grating structure on the interface between the lower surface of an absorption layer and a substrate provided by the present invention;

FIG. 6 is a schematic structure diagram of a photodetector with a Bragg reflector on a substrate provided by the present invention,

FIG. 7 is a schematic structure diagram of a photodetector with a grating structure on the upper surface of a light absorption layer provided by the present invention.

### DESCRIPTION OF REFERENCE CHARACTERS

10. substrate; 101. light reflection layer; 20. optical structure;
201. optical waveguide; 202. light absorption layer.

### DETAILED DESCRIPTION OF THE EMBODIMENTS

In order to make the objectives, technical solutions, and advantages of the present invention more apparent and understandable, the technical solutions according to embodiments of the present invention are clearly and completely described in the following with reference to the accompanying drawings. Apparently, the embodiments in the following description are merely a part rather than all of the embodiments of the present invention. All other embodiments obtained by persons of ordinary skill in the art based on the embodiments of the present invention without creative efforts shall fall within the protection scope of the present invention. Unless otherwise defined, the technical or scientific terms used herein should be understood in the general sense by persons of ordinary skill in the art to which the present invention belongs. The terms such as “include/comprise” or similar words refer to that an element or item preceding the term encompasses the elements or items listed subsequent to the term and their equivalents, without excluding other elements or items.

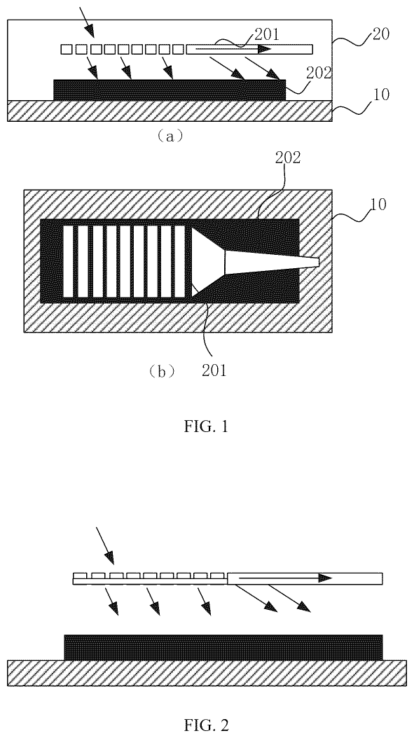

In view of the problems existing in the prior art, embodiments of the present invention comprises a photodetector 10. FIG. 1(a) shows a cross-sectional view of a photodetector, and FIG. 1(b) shows a top view of a photodetector. The photodetector comprises a substrate 10 and an optical structure 20 formed on the substrate 10.

The optical structure 20 comprises an optical waveguide 201 and a light absorption layer 202. The optical waveguide 201 is suspended above the upper side of the light absorption layer 202 and includes a first section and a second section, wherein the first section features a grating structure, and the second section features a tapered structure, the grating structure is designed to diffract incident light and alter the propagation direction of a portion of light. For example, FIG. 1(b) shows that the first section of the optical waveguide 201 can be a uniform grating structure or a non-uniform grating structure.

In this embodiment, the optical waveguide can be made of one or more materials, including but not limited to silicon, silicon nitride, silicon oxynitride, silicon dioxide, polymers, lithium niobate, indium phosphide, aluminum oxide, and the like. The optical waveguide can take various forms, such as channel waveguides, ridge waveguides, slot waveguides, diffused waveguides, photonic crystal waveguides, or other types. The tapered waveguide can exist not only along a straight line but also in forms such as spirals, rings, or folded shapes. The tapered structure can feature various profile curves, including linear, quadratic, parabolic, Euler, and Bezier curves. The optical waveguide can exist on a single layer or a plurality of layers.

The light absorption layer 202 is arranged on the substrate 10 and configured to absorb light diffracted through the optical waveguide 201. Optionally, the light absorption layer 202 can be made of various materials, including but not limited to germanium, silicon, metals, III-V materials, and the like. In addition, the light absorption layer 202 can take on shapes such as a cube, a cylinder, a cone, a pyramid, a groove, a ring, or other forms. The absorption layer may consist of a single layer or a plurality of layers.

In this embodiment, the photodetector can be based on various operating principles, such as a PIN diode, a metal-semiconductor-metal photodetector, an avalanche photodiode, and the like. In this embodiment, the orientation of a junction in a photodiode may be either transverse or vertical. The junction can also be designed in complex shapes, such as L shapes or U shapes.

It is worth noting that FIG. 1(b) shows that the first section of the optical waveguide 201 is a fully etched grating, meaning that the grating structure can be fabricated by completely etching the first section of the optical waveguide; and in another possible embodiment, FIG. 2 shows that the first section of the optical waveguide 201 is a shallow etched grating, which implies that the grating structure can be fabricated by partially etching the first section of the optical waveguide.

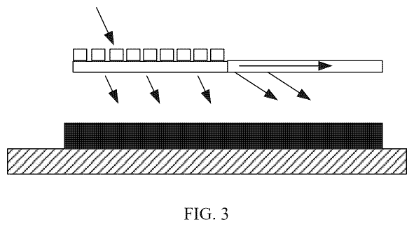

In another possible embodiment, as shown in FIG. 3, the upper surface of the first section features a grating structure and constitutes a facet of the light absorption layer, situated away from the optical waveguide. In one case, an alternative material could be arranged on the upper surface of the first section of the waveguide to form the grating structure; and in another case, the same material used in the first section of the waveguide could be utilized on the upper surface to form the grating structure, so as to fabricate a grating structure as shown in a view of the photodetector in FIG. 3. It should be understood that the alternative material or the same material arranged on the upper surface of the first section might either cover the upper surface of the first section or possess a specific gap between it and the upper surface of the first section.

In another possible embodiment, the lower surface of the first section features a grating structure (not shown in the figure), and constitutes a facet of the light absorption layer adjacent to the optical waveguide. In one case, an alternative material could be arranged on the lower surface of the first section of the waveguide to form the grating structure; and in another case, the same material used in the first section of the waveguide could be utilized on the lower surface of the first section of the waveguide to form the grating structure, so as to fabricate a grating structure. It should be understood that the alternative material or the same material arranged on the lower surface of the first section might either cover the lower surface of the first section or possess a specific gap between it and the lower surface of the first section.

As shown in FIG. 2 or FIG. 3, a portion of the external incident light passes through the grating structure of the optical waveguide 201, entering the light absorption layer 202 from above and getting absorbed, while another portion of the light becomes coupled to the grating structure. An arrow in FIG. 2 illustrates the direction of incidence or diffraction or penetration or propagation. The second section of the optical waveguide is configured as the tapered structure, allowing the size of the light beam to gradually expand and be smoothly coupled into an absorption region, as shown in FIG. 2. As a result, the incident light can be gradually absorbed during the propagation along the waveguide, thereby achieving a higher photoelectric conversion efficiency. It can be seen from FIG. 2 that the grating can be designed as required so that the light from any angle of incidence can propagate in any desired direction, improving the interaction between the light and an absorbing material. In addition, the grating can be designed with different coupling coefficients, allowing adjustment of the ratio of the power of entering light in the optical waveguide to that of the incident light, for instance, 50%, 80%, or any other proportion as needed.

Compared to the prior art, where conventional photodetectors lack a grating structure, all incident light directly enters the absorption region, with a portion of the light penetrating through the substrate, leading to some optical loss and thus low photoelectric conversion efficiency. In contrast, the photodetector provided by the present application enables a portion of the incident light to be coupled into the optical waveguide and then be absorbed by the light absorption layer during the propagation along the optical waveguide, leading to a higher photoelectric conversion efficiency of the photodetector. Additionally, the grating structure not only increases the responsivity of the photodetector but also improves its ability to withstand large amounts of incident light, thereby avoiding saturation or damage. In the conventional photodetector without the grating structure, intense light incidence can lead to saturation or loss of the photodetector. In this embodiment, a portion of the light is guided into the waveguide and then gradually absorbed by the light absorption layer, as compared to the conventional photodetector, this design allows for the handling of higher optical illumination intensities without experiencing saturation.

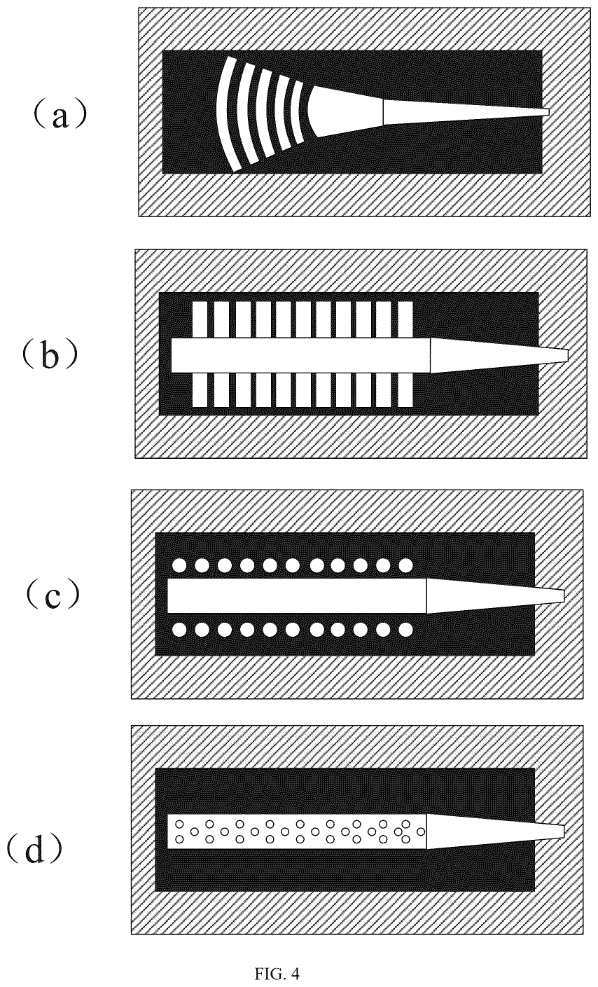

In a possible embodiment, as shown in the top view of FIG. 4(a), the grating may have a focusing effect, exhibiting a bent shape; alternatively, as shown in the top view of FIG. 4(b), the grating might feature rectangular side corrugations; alternatively, as shown in the top view of FIG. 4(c), the grating might feature circular side pillars; alternatively, as shown in the top view of FIG. 4(d), the grating might feature photonic crystal holes in the waveguide.

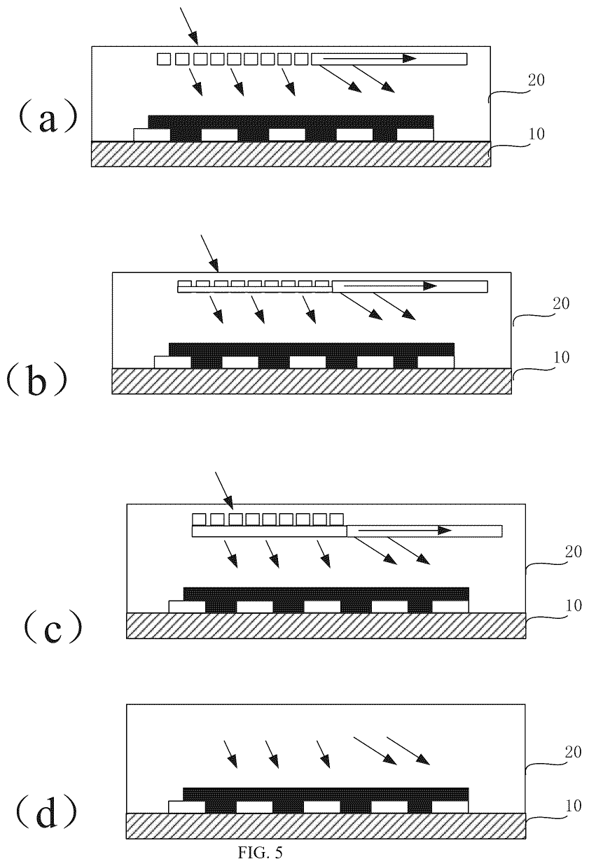

In a possible embodiment, a grating structure is arranged on the lower surface of the light absorption layer adjacent to the optical waveguide, as shown in FIG. 5. Another grating structure might be arranged on the interface between the lower surface of the light absorption layer and the substrate. Specifically, in this embodiment, a Bragg reflection grating structure could be formed on the bottom surface of the substrate using fabrication processes such as film deposition, photolithography, etching, and other processes, such that the light emitted toward the substrate can be diffracted or reflected to the absorption region at any desired angle, thereby further increasing the responsivity. For example, a corresponding photodetector provided with a grating structure on the lower surface of a light absorption layer can be shown in FIG. 5(a), FIG. 5(b), or FIG. 5(c). It is worth noting that a corresponding photodetector provided with a grating structure on the upper surface of a light absorption layer can be made without the upper-layer waveguide grating, as shown in FIG. 5(d).

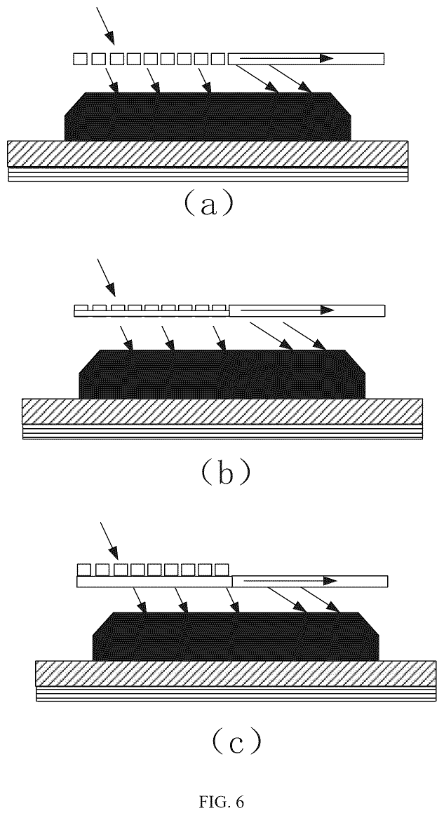

In another possible embodiment, a light reflection layer 101 is arranged on the lower surface of the substrate away from the light absorption layer, as shown in FIG. 6, such that the light emitted toward the substrate can be reflected to the absorption region at any desired angle, thereby further increasing the responsivity. For example, a corresponding photodetector provided with a light reflection layer on the lower surface of a substrate can be shown in FIG. 6(a), FIG. 6(b), or FIG. 6(c).

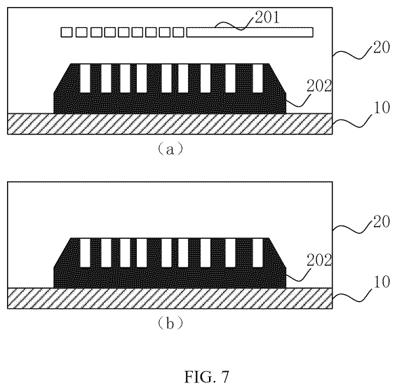

In another possible embodiment, a grating structure is arranged on the upper surface of the light absorption layer adjacent to the optical waveguide, as shown in FIG. 7, such that light emitted toward the substrate can be reflected to the absorption region at any desired angle, thereby further increasing the responsivity. For example, a corresponding photodetector provided with a light reflection layer on the surface of the substrate can be shown in FIG. 7(a); alternatively, a corresponding photodetector provided with a light reflection layer on the surface of the substrate can be made without the optical waveguide, as shown in FIG. 7(b).

The operating wavelength range of the photodetector encompasses at least one of the visible light band, O band, E band, S band, C band, L band, U band, and mid-infrared band. The waveguide grating of the photodetector can be designed to operate within one or multiple wavelength ranges as required Parameters such as bandwidth, intensity, sidelobes, and losses of the waveguide grating of the photodetector can also be designed or adjusted to suit the application requirements.

The waveguide grating of the photodetector can have a uniform or non-uniform periodicity. The etching depth, width, thickness, and other dimensions of the waveguide grating of the photodetector can be uniform or non-uniform.

The shape, length, width, thickness, and other dimensions of the absorption region of the photodetector can be designed or adjusted according to suit the application requirements.

In a possible embodiment, the present application also provides a photodetector array, such as a single photon detector array or a silicon photomultiplier tube, which includes a plurality of light sensing units distributed in an array format, wherein each light sensing unit incorporating the photodetector described in any one embodiment of the present application. Each unit can operate within the same or different wavelength ranges. Each unit may exhibit the same or different optical responsivity. Each unit can be built upon different structure designs.

In a possible embodiment, the present application further provides a photonic chip, which encompasses the photodetector or the photodetector array described in any one of the above embodiments. The photonic chip could serve as a ranging chip, depth imaging chip, time-of-flight chip, and the like.

In a possible embodiment, the present application also provides a photodetection terminal equipment, which comprises a terminal equipment body and the above photodetector array connected to each other, wherein the terminal equipment body is capable of performing photodetection by the photodetector array as described in any one embodiment of the present application. The above photodetection terminal equipment could encompass various terminal equipment, such as photosensitive ranging equipment, mobile communication equipment, image processing equipment, optical sensing equipment, optical interconnection equipment, and the like.

Although the embodiments of the present invention are described in detail above, it is obvious to those skilled in the art that various modifications and changes can be made to these embodiments. However, it should be understood that such modifications and changes fall within the scope and spirit of the present invention as described in the claims. Furthermore, the present invention described herein may have other embodiments and may be carried out or implemented in various ways.

1. A photodetector, comprising a substrate and an optical structure formed on the substrate, wherein the optical structure comprises an optical waveguide and a light absorption layer;
the optical waveguide is suspended above an upper side of the light absorption layer and includes a first section and a second section, wherein the first section has a grating structure, and the second section has a tapered structure, the grating structure is configured to diffract incident light and alter the propagation direction of a portion of light;
the light absorption layer is arranged on the substrate and configured to absorb light passing through the grating structure or a portion of light diffracted through the grating structure.

2. The photodetector according to claim 1, wherein the grating structure is a fully etched grating structure or a shallow etched grating structure, or the grating structure is a multilayer structure.

3. The photodetector according to claim 2, wherein a grating of the grating structure is bent in a curved shape that focuses toward the second section.

4. The photodetector according to claim 2, wherein a grating of the grating structure has rectangular side corrugations.

5. The photodetector according to claim 2, wherein a grating of the grating structure has circular side pillars.

6. The photodetector according to claim 2, wherein a grating of the grating structure has photonic crystal holes.

7. The photodetector according to claim 1, wherein the grating structure is arranged on an interface between a lower surface of the light absorption layer and the substrate;
the grating structure is configured to reflect light projected through an absorption layer back toward the light absorption layer.

8. The photodetector according to claim 1, wherein a light reflection layer is arranged on a lower surface of the substrate.

9. The photodetector according to claim 8, wherein the light reflection layer comprises any one of a Bragg reflector, a metal reflector, and a reflective film.

10. The photodetector according to claim 1. wherein the grating structure is arranged on an upper surface of the light absorption layer adjacent to the optical waveguide.

11. The photodetector according to claim 1, wherein a surface of the first section has a grating structure.

12. The photodetector according to claim 1, further comprising a circuit layer electrically connected to the light absorption layer, wherein the circuit layer is configured to convert light signals absorbed by the light absorption layer into electrical signals.

13. A photodetector array, comprising a plurality of photodetectors distributed in an array, wherein each of the photodetectors is the photodetector according to claim 1.

14. A photodetector terminal equipment comprising: a terminal equipment body;
and the photodetector array connected to the terminal equipment body according to claim 13, wherein the terminal equipment body performs photodetection by the photodetector array.
